(19) United States
(12) Patent Application Publication
(10) Pub. No.: US 2009/0166760 A1
(43) Pub. Date: Jul. 2, 2009

(54) Semiconductor Device and Method of Manufacturing the Same

(76) Inventor: Dong Han RYU, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/326,052

(22) Filed: Dec. 1, 2008

(30) Foreign Application Priority Data
Dec. 26, 2007 (KR) 10-2007-0137900

(51) Int. Cl. H01L 27/105; H01L 21/336

(52) U.S. Cl. 257/401; 438/197; 257/E21.409; 257/E27.081

(57) ABSTRACT

Disclosed are a semiconductor device and a manufacturing method thereof. The semiconductor device includes a gate electrode in a first trench in a semiconductor substrate, a ground area in a second trench facing the gate electrode, and source and drain areas in third and fourth trenches at ends of the gate electrode, respectively. A transistor having a micro-size is obtained, so that a semiconductor chip having a micro-size and a high integration degree may be realized.

The present application claims priority under 35 U.S.C. 119 and 35 U.S.C. 365 to Korean Patent Application No. 10-2007-0137900 (filed on Dec. 26, 2007), which is hereby incorporated by reference in its entirety.

### BACKGROUND

With the rapid development of information technologies, information media, such as computers, have been extensively used so that semiconductor devices also make rapid progress. In functional aspects, the semiconductor devices have tended toward higher integration, so that various methods have been researched and developed to maximize performance of semiconductor devices while reducing a feature size of an individual device formed on the semiconductor substrate.

At present, a transistor having a MOS (metal-oxide-semiconductor) structure is basically used for a semiconductor chip. According to the MOS transistor structure, layers are horizontally stacked to form a semiconductor device. Such a structure has been employed in the semiconductor device from the early stage of the semiconductor device up to now. However, as the semiconductor device has been highly integrated, a gate CD (critical dimension) has been reduced, so that the above structure causes a problem in the manufacturing process of the semiconductor device.

In order to solve the above problem, it is necessary to develop photolithography and etch processes for defining micro designs (according to design rules) and to improve a cleaning process. In addition, it is also necessary to develop deposition technology, control technology for implantation processes, and technology for maintaining and managing the FAB (fabrication facility) environment to reduce defects.

In particular, in order to improve the integration degree and to solve the problems derived from the conventional process, there has been suggested a method of providing a new transistor model by modifying the conventional transistor structure.

### SUMMARY

Embodiments of the invention provide a semiconductor device and a method of manufacturing the same, capable of improving an integration degree of the semiconductor device by modifying a structure of the transistor and realizing a transistor having a micro size using a low-level semiconductor manufacturing technology.

According to various embodiments, a semiconductor device may include a gate electrode in a first trench in a semiconductor substrate, a ground area in a second trench facing the gate electrode, and source and drain areas in third and fourth trenches at ends of the gate electrode.

According to other embodiments, a method of manufacturing the semiconductor device is provided. The method includes the steps of forming first to fourth trenches in a semiconductor substrate, forming an oxide layer in the first to fourth trenches, filling the first to fourth trenches with a polysilicon layer, and forming a gate electrode, a ground area, a source area, and a drain area in the first to fourth trenches, respectively, by performing an implantation process on the polysilicon layer.

According to the embodiments, a transistor having a micro size can be obtained by modifying a structure of a conventional transistor, so that miniaturization and high integration of a semiconductor chip can be realized.

According to the embodiments, a transistor having an improved structure can be fabricated by using a low-level semiconductor manufacturing technology, so that the manufacturing cost can be reduced, and the product yield can be improved.

In addition, the manufacturing cost can be saved by simplifying the manufacturing process for the semiconductor device, and a new technology for manufacturing a transistor having an improved structure can be established.

### BRIEF DESCRIPTION OF THE DRAWINGS

FIG. 1 is a plan view showing an exemplary transistor according to a first embodiment;

FIG. 2 is a plan view showing an exemplary transistor according to a second embodiment, and FIG. 3 is a perspective view showing the exemplary transistor according to the second embodiment;

FIGS. 4 and 5 are a plan view and a perspective view showing an exemplary first step of manufacturing a semiconductor device according to various embodiments;

FIG. 6 is a plan view showing an exemplary second step of manufacturing a semiconductor device according to various embodiments;

FIG. 7 is a plan view showing an exemplary third step of manufacturing a semiconductor device according to various embodiments;

FIG. 8 is a plan view showing an exemplary fourth step of manufacturing a semiconductor device according to various embodiments;

FIG. 9 is a plan view showing an exemplary fifth step of manufacturing a semiconductor device according to various embodiments;

FIG. 10 is a perspective view showing an exemplary transistor manufactured according to various embodiments;

FIG. 11 is a plan view showing an exemplary transistor structure according to another embodiment;

FIG. 12 is a plan view showing an exemplary transistor structure of a semiconductor device according to yet another embodiment;

FIG. 13 is a plan view showing an exemplary transistor structure according to still another embodiment;

FIG. 14 is a plan view showing an exemplary transistor according to another embodiment; and

FIG. 15 is a plan view showing an exemplary transistor according to a further embodiment.

### DETAILED DESCRIPTION OF THE EMBODIMENTS

Hereinafter, a semiconductor device and a method of manufacturing the same according to embodiments of the invention will be described in detail with reference to accompanying drawings. Although the preferred embodiments of the present invention have been disclosed for illustrative purposes, those skilled in the art will appreciate that various modifications, additions, deletions and substitutions are possible without departing from the scope and sprit of the invention as disclosed in the accompanying claims.

The terms “first” and “second” described below are used to distinguish members of a group from each other and to represent at least two members, not necessarily to define the members. Accordingly, if the terms “first” and “second” are mentioned, plural members are generally provided, and the members can be selectively or alternatively used. The size (dimension) of elements shown in the drawings may be magnified for the purpose of clear explanation, and the real size of the elements may be different from the size of the elements shown in drawings. In addition, the present invention may not include all the elements shown in the drawings and may not be limited thereto. The elements except for essential elements of the present invention can be omitted or added without limitation. In the description of the embodiment, it will be understood that, when a layer (or film), a region, a pattern, or a structure is referred to as being “on(above/over/upper)” or “under(below/down/lower)” another substrate, another layer (or film), another region, another pad, or another pattern, it can be directly on the other substrate, layer (or film), region, pad or pattern, or intervening layers may also be present. Furthermore, it will be understood that, when a layer (or film), region, pattern, pad, or structure is referred to as being “between” two or more layers (or films), regions, pads or patterns, it can be the only layer between the two or more layers (or films), regions, pads, or patterns, or one or more intervening layers may also be present. Thus, the meaning should be determined by in the context of the technical idea of the invention.

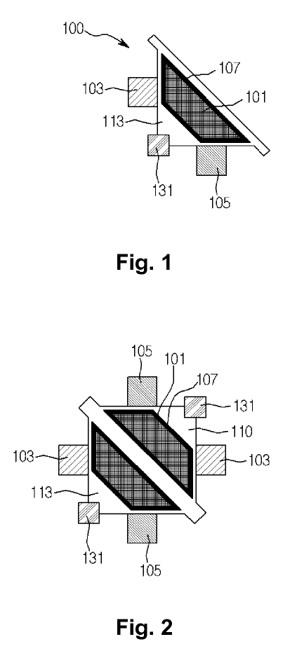

FIG. 1 is a plan view showing an exemplary transistor according to a first embodiment.

As shown in FIG. 1, the exemplary transistor 100 includes a gate electrode 101, a source area 103, a drain area 105, and a ground area 131, which are formed on an active area of a semiconductor substrate 110. As may be the case, the source area 103 and drain area 105 may be reversed, and both source area 103 and drain area 105 may be referred to herein as “source/drain terminals.” A channel area 113 is between the source area 103 and the drain area 105.

The source area 103, the drain area 105, the ground area 131 and the channel area 113 are doped with impurities according to the characteristics thereof. The dopant impurities may comprise N-type impurities (e.g., P. As, and/or Sb) or P-type impurities (e.g., B).

The gate electrode 101, the source area 103, the drain area 105, and the ground area 131 are formed by filling trenches 101a, 103a, 105a and 131a with polysilicon. A gate oxide layer 107 may be formed along the walls of the trenches 101a, 103a, 105a and 131a prior to depositing the polysilicon.

When viewed in a plan view, the transistor 100 has a triangular structure, in which the source area 103 and the drain area 105 are formed on opposite, lateral (or orthogonal) sides of the triangle, and the gate electrode 101 is formed on a bottom side of the triangular structure, respectively. The ground area 131 may be formed at a vertex of the triangular structure (e.g., facing the gate electrode 101), and the channel area 113 has an area defined by the gate electrode 101, the source area 103, the drain area 105 and the ground area 131.

According to the transistor 100 having the structure as shown in FIG. 1, the gate electrode 101, the source area 103, the drain area 105 and the ground area 131 can be simultaneously formed on the semiconductor substrate 110 through a trench etching and deposition process. In addition, the gate oxide layer 107 can be formed on surfaces (e.g., including the sidewalls) of the trenches 101a, 103a, 105a and 131a through an oxidation process. That is, the gate oxide layer 107 is grown perpendicularly to the sidewalls of the trenches 101a, 103a, 105a and 131a, so that the channel is formed in the vicinity of the trenches 101a, 103a, 105a and 131a, which is similar to a side profile of the conventional MOS transistor.

In addition, according to the exemplary embodiments, the length and thickness of the channel 113 of the transistor can be adjusted by controlling the trench etching process and the oxidation process, (instead of or in addition to other parameters, such as the gate CD control). Therefore, according to the exemplary transistor 100, a micro-sized semiconductor device can be realized without employing a high-level semiconductor manufacturing technology, and the integration degree of the semiconductor device can be improved.

FIG. 2 is a plan view showing an exemplary transistor according to a second embodiment, and FIG. 3 is a perspective view showing the exemplary transistor according to the second embodiment.

Referring to FIGS. 2 and 3, a pair of transistors, which are substantially identical to the transistor shown in FIG. 1, are provided in a mirror arrangement. The plane of symmetry may be defined by a vertical plane passing through the most distant corners of the square structure (e.g., the corners occupied by ground nodes 131). The operation and structure of the transistors shown in FIGS. 2 and 3 are substantially identical to those of the transistor shown in FIG. 1.

The transistor according to the second embodiment includes gate electrodes 101, disposed in parallel to each other, source and drain areas 103 and 105 formed at sides of the gate electrodes 101 (or orthogonal sides of the triangular-shaped transistor), respectively, and ground areas 131 formed on vertexes facing the gate electrodes 101. When viewed in a plan view, the two-transistor structure has a square or rectangular shape.

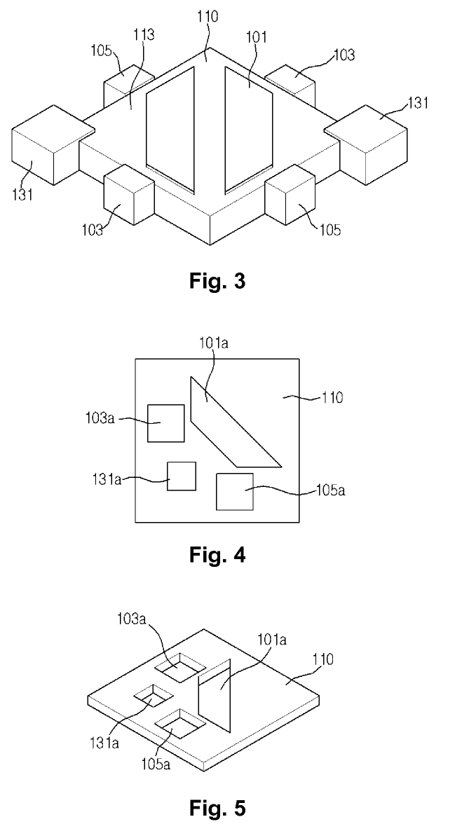

FIGS. 4 and 5 are a plan view and a perspective view showing a first exemplary step of manufacturing the semiconductor device according to various embodiments.

As shown in FIGS. 4 and 5, the active area is formed (or defined) on the semiconductor substrate 110. The active area may be defined by an isolation layer pattern formed or buried in the semiconductor substrate 110. For example, the isolation layer pattern may comprise a shallow trench isolation (STI) structure and/or a local oxidation of silicon (LOCOS) structure, formed by the respective technique(s). The isolation layer pattern may be located along the edges or borders of the active area 110, surrounding the gate trench 101a, the source trench 103a, the drain trench 105a, and the ground trench 131a. Alternatively, the isolation layer pattern maybe along the long edge of the gate trench 101a, surrounding the same four trenches.

Then, the trenches 101a, 103a, 105a and 131a are formed in predetermined areas of the semiconductor substrate 110 which are intended as the gate electrode area, the source area, the drain area and the ground area, respectively. That is, a photoresist film is coated on the semiconductor substrate 110, and a photoresist pattern is formed by selectively exposing and developing the photoresist film. Then, the semiconductor substrate is etched to a predetermined depth using the photoresist pattern as an etch mask, thereby forming the trenches 101a, 103a, 105a and 131a.

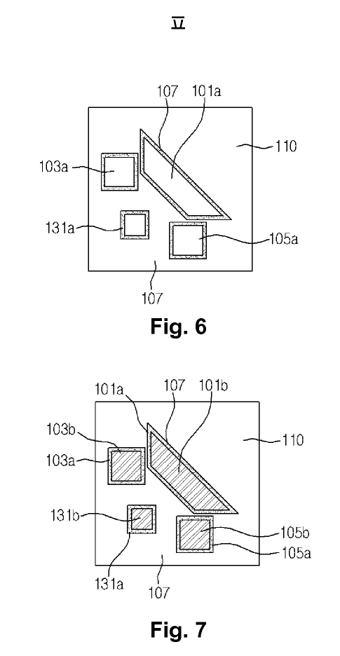

FIG. 6 is a plan view showing an exemplary second step of manufacturing the semiconductor device according to the embodiments.

As shown in FIG. 6, the semiconductor substrate 110 having the trenches 101a, 103a, 105a and 131a is subject to a thermal oxidation process to form a gate oxide layer 107 on the exposed silicon surface of the substrate 110 and in the trenches 101a, 103a, 105a and 131a (including on the bottom and sidewalls thereof).

FIG. 7 is a plan view showing an exemplary third step of manufacturing the semiconductor device according to the embodiments.

As shown in FIG. 7, a polysilicon layer is formed on the semiconductor substrate 110 having the trenches 101a, 103a, 105a and 131a therein. The polysilicon layer is deposited on the entire surface of the semiconductor substrate 110 such that the trenches 101a, 103a, 105a and 131a fill up with the polysilicon layer. Such deposition may comprise chemical vapor deposition from a silicon source of the formula SiₓH_{y}X_{z}, where 1≦x≦4 and y+z=2x+2, such as silane (SiH4), dichlorosilane (SiH2Cl2), disilane (Si2H6), etc., optionally in the presence of a reducing agent such as H2 and/or a dopant source such as diborane (B2H6), phosphine (PH3), arsine (AsH3) or trisilylarsine (Ar[SiH3]3), etc.

The polysilicon layer is planarized through a chemical mechanical polishing process, thereby forming a polysilicon pattern in the trenches 101a, 103a, 105a and 131a. As a result, a preliminary gate electrode 101b, a preliminary source area 103b, a preliminary drain area 105b and a preliminary ground area 131b are formed. The chemical mechanical polishing process may also remove the oxide formed on the uppermost surface of the substrate 110 during oxidation of the surfaces of the trenches 101a, 103a, 105a and 131a.

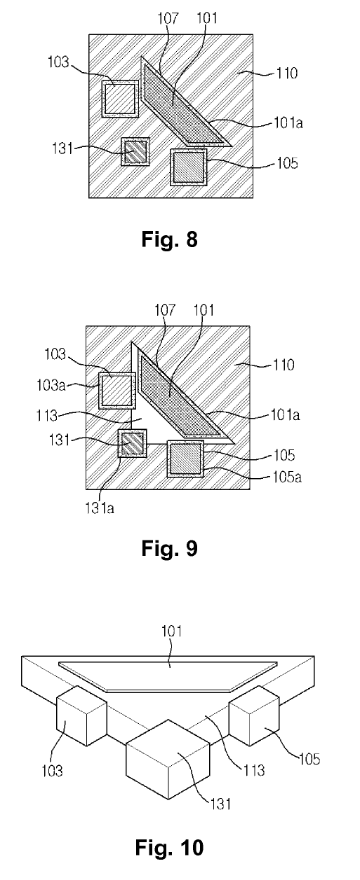

FIG. 8 is a plan view showing an exemplary fourth step of manufacturing the semiconductor device according to the embodiments.

As shown in FIG. 8, an ion implantation process is performed on the preliminary gate electrode 101b, the preliminary source area 103b, the preliminary drain area 105b and the preliminary ground area 131b in the semiconductor substrate 110 such that a predetermined resistance can be properly obtained for the above areas. For instance, N-type impurities can be heavily doped into the polysilicon pattern formed in the preliminary source area 103b and the preliminary drain area 105b. However, one may mask the region encompassing the channel 113 if desired prior to such ion implantation. As a result, the gate electrode 101, the source area 103, the drain area 105 and the ground area 131 can be formed in the trenches 101a, 103a, 105a and 131a of the semiconductor substrate 110, respectively.

FIG. 9 is a plan view showing an exemplary fifth step of manufacturing the semiconductor device according to the embodiments.

Referring to FIG. 9, a channel implantation process is performed between the source area 103 and the drain area 105 to form the channel area 113 (which may also be further defined by the gate electrode 101). The first ion implantation (see the discussion of FIG. 8 above) and the second ion implantation (FIG. 9) are each conducted at a dose and energy providing a predetermined threshold voltage for the transistor 100.

Thus, the channel area 113 maybe defined by the sidewalls of the gate electrode 101, the source area 103 and the drain area 105.

FIG. 10 is a perspective view showing the exemplary transistor manufactured according to the exemplary method.

As shown in FIG. 10, the gate electrode 101 is formed on the longest lateral side of the triangular active area defined on the semiconductor substrate 110. The source area 103 and the drain area 105 are formed on two lateral (orthogonal) sides of the triangular active area (e.g., facing each other and/or the gate 101). The ground area 131 is formed on the vortex of the triangular active area (e.g., facing the gate electrode 101). It is within the abilities of one skilled in the art to form insulation/dielectric layers over the transistor of FIG. 10, as well as metallization (e.g., local interconnects or overlying metal layers) and/or contacts to each of the gate electrode 101, the source area 103, the drain area 105, and the ground area 131.

In addition, a predetermined portion of the active area defined by the gate electrode 101, the source area 103 and the drain area 105 may serve as the channel area 113.

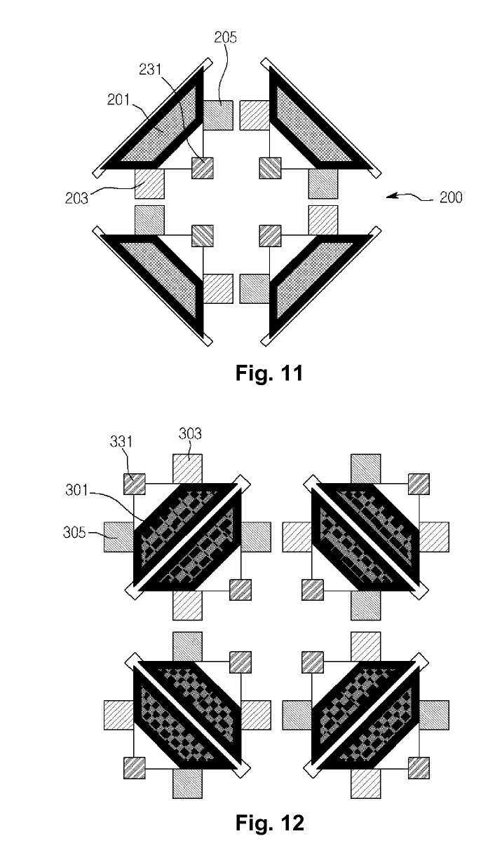

FIG. 11 is a plan view showing an exemplary transistor structure according to another embodiment.

The exemplary transistor structure 200 shown in FIG. 11 can be obtained by arranging four transistors shown in FIG. 1 in four (substantially orthogonal) directions.

Ground areas 231 of the four transistors are arranged at an inner portion of the transistor structure 200, such that the vertices of the triangular active areas are adjacent to one another, and the transistor structure 200 has a substantially rectangular or square shape. In addition, gate electrodes 201 may be disposed around the rectangular transistor structure 200, while source areas 203 and drain areas 205 maybe between the gates 201 of the triangular transistor structures. The transistors may be easily connected in series in such a layout. Also, the source, drain and ground area of a first pair of opposed transistors in such a layout (as opposed to adjacent transistors) may be doped with a first type of dopant, whereas the remaining transistors may be doped with a second, complementary dopant.

FIG. 12 is a plan view showing an exemplary transistor structure according to yet another embodiment.

Referring to FIG. 12, the exemplary transistor structure includes gate electrodes 301, ground areas 331, source areas 303 and drain areas 305. The exemplary transistor structure of FIG. 12 can be obtained by arranging four transistor structures according to FIG. 3, in which each transistor structure includes two transistors symmetrically formed in a mirror arrangement, in four directions (e.g., arranged as a 2×2 matrix). The source, drain and ground area of a first two-transistor structure in such a layout may be doped with a first type of dopant, whereas a laterally adjacent two-transistor structure (as opposed to a diagonally adjacent two-transistor structure) may be doped with a second, complementary dopant.

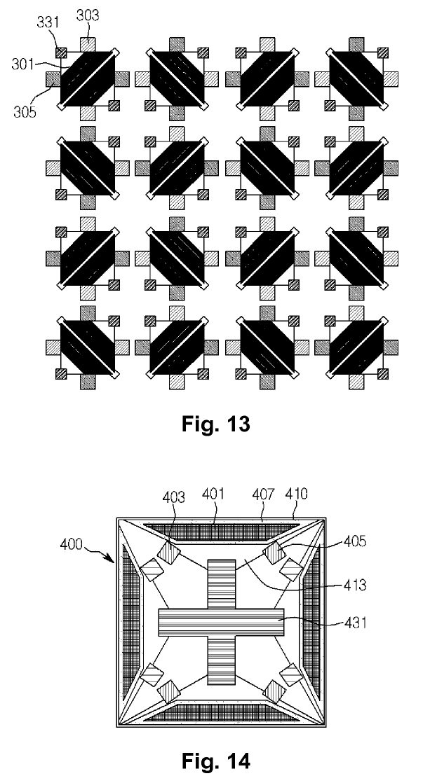

FIG. 13 is a plan view showing an exemplary transistor structure of according to a further embodiment.

Referring to FIG. 13, the exemplary transistor structure includes a plurality of transistors which are regularly arranged in the form of an array.

According to the exemplary structure of FIG. 13, the transistors can be formed at angular edges of the semiconductor device, so the space utilization can be improved and productivity of semiconductor chips having a high integration degree can be increased.

FIG. 14 is a plan view showing an exemplary transistor structure of according to yet another embodiment.

Referring to FIG. 14, a vertex of each triangular active area in the transistor structure 400, on which a ground area 431 is formed, has an obtuse angle (e.g., other than a right angle). The transistor structure includes gate electrodes 401, source areas 403, and drain areas 405 on three lateral sides of the triangular transistor structure, respectively. The ground area 431 is formed between the source area 403 and the drain area 405.

Gate oxide layers 407 are on at least sidewalls of the gate electrodes 401 adjacent to the channel areas 413.

According to the exemplary structure of FIG. 14, the ground area 431 formed in the inner portion of the transistor structure 400 may have a cross shape such that the single ground area 431 can be connected to each transistor.

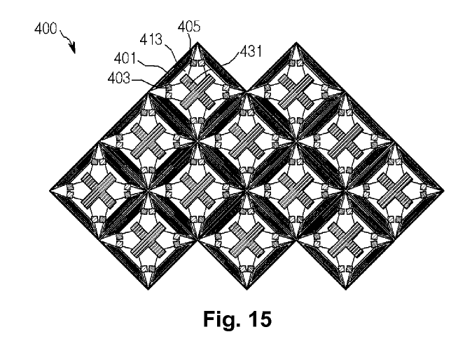

FIG. 15 is a plan view showing an exemplary transistor structure according to still another embodiment.

Referring to FIG. 15, the exemplary transistor structure can be obtained by regularly arranging a plurality of transistor structures, which are substantially identical to the transistor structure shown in FIG. 14, in the form of an array.

According to the various embodiments, the transistors can be formed at angular edges of the semiconductor device, so the space utilization can be improved and productivity of semiconductor chips having a high integration degree can be increased.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a gate electrode in a first trench in a semiconductor substrate;
a ground area in a second trench facing the gate electrode; and
source and drain areas in third and fourth trenches at side ends of the gate electrode.

2. The semiconductor device as claimed in claim 1, further comprising a channel area between the source area and the drain area.

3. The semiconductor device as claimed in claim 2, wherein the channel area is along a sidewall of the first trench.

4. The semiconductor device as claimed in claim 1, further comprising a gate oxide layer on a sidewall of the first trench.

5. The semiconductor device as claimed in claim 1, comprising an active area having a triangular shape, wherein the ground area is on a vertex of the active area.

6. The semiconductor device as claimed in claim 5, wherein the gate electrode is on a longest lateral side of the active area.

7. The semiconductor device as claimed in claim 6, wherein the vertex has a right angle or an obtuse angle.

8. The semiconductor device as claimed in claim 1, wherein the gate electrode, the ground area, and the source and drain areas include a polysilicon pattern in the first to fourth trenches, respectively.

9. The semiconductor device as claimed in claim 1, comprising a pair of transistors, each including a gate electrode, a ground area, and source and drain areas, aligned in a mirror arrangement such that the gate electrodes of the pair of transistors face each other.

10. The semiconductor device as claimed in claim 9, comprising four transistor structures, in which each transistor structure includes the pair of transistors symmetrically aligned in the mirror arrangement.

11. The semiconductor device as claimed in claim 1, comprising four transistors including gate electrodes, ground areas, and source and drain areas aligned symmetrically to each other.

12. The semiconductor device as claimed in claim 11, wherein the ground areas are at center portions of the transistors.

13. The semiconductor device as claimed in claim 12, wherein the ground areas are connected to each other.

14. The semiconductor device as claimed in claim 12, further comprising a ground connection having a cross shape.

15. A method of manufacturing a semiconductor device, the method comprising the steps of:
forming first to fourth trenches in a semiconductor substrate;
forming an oxide layer in the first to fourth trenches;
filling the first to fourth trenches with a polysilicon layer; and
forming a gate electrode, a ground area, a source area, and a drain area in the first to fourth trenches, respectively, by performing an implantation process on the polysilicon layer.

16. The method as claimed in claim 15, comprising a channel having a length and a width determined by a sidewall of the first trench.

17. The method as claimed in claim 15, comprising forming a pair of transistors including gate electrodes, ground areas, and source and drain areas aligned in a mirror arrangement such that the gate electrodes face each other.

18. The method as claimed in claim 15, further comprising forming a channel area between the source area and the drain area by channel implantation in a region defined by the gate electrode, the source area and the drain area, after forming the source and drain areas.

19. The method as claimed in claim 15, wherein the first trench is formed at a longest lateral side of a triangular active area, the second trench is formed at a vertex of the triangular active area, and the third and fourth trenches are formed at ends of the first trench.

20. The method as claimed in claim 15, wherein forming the oxide layer comprises thermally oxidizing the semiconductor substrate.
